(19) United States
(12) Patent Application Publication
(10) Pub. No.: US 2024/0326175 A1
(43) Pub. Date: Oct. 3, 2024

(54) WAFER THINNING METHOD

(71) Applicant: DISCO CORPORATION, Tokyo (JP)

(72) Inventor: Asahi NOMOTO, Tokyo (JP)

(21) Appl. No.: 18/609,222

(22) Filed: Mar. 19, 2024

(30) Foreign Application Priority Data
Mar. 29, 2023 (JP) 2023-053877

(51) Int. Cl. B23K 26/55

(52) U.S. Cl. CPC B23K 26/55

(57) ABSTRACT

A wafer thinning method for a wafer includes bonding a first support substrate to a first surface of the wafer, positioning a focused spot of a laser beam with a wavelength transmittable through the wafer from a second surface side of the wafer inside the wafer, and applying the laser beam while moving the focused spot and the wafer relative to each other in a direction parallel to the second surface, thereby forming separation start points each including a modified layer parallel to the second surface and cracks extending from the modified layer, applying an ultrasonic wave to the wafer from the second surface side of the wafer, bonding a second support substrate to the second surface of the wafer, and separating the wafer at the separation start points into a first wafer having the first surface and a second wafer having the second surface, thereby thinning the wafer.

### BACKGROUND OF THE INVENTION

### Field of the Invention

The present invention relates to a wafer thinning method.

### Description of the Related Art

Lithium tantalate (LiTaO₃) is used as a substrate for a surface acoustic wave (SAW) filter. However, because lithium tantalate has a large thermal expansion coefficient, frequency-shift attributable to a rise in temperature is generated, which is considered problematic. To address this problem, there has been designed such a method of bonging a wafer such as silicon or sapphire having a small thermal expansion coefficient to a lithium tantalate wafer as a support substrate to suppress thermal expansion, thereby enhancing a frequency-temperature characteristic. The bonded wafer thus formed is thinned through grinding or the like, subjected to patterning, and diced along crossing division lines into individual device chips.

However, when such a lithium tantalate wafer is ground, severe wear of grindstones is caused, leading to significantly poor economy. Moreover, grinding the lithium tantalate wafer is time consuming, causing lowering of the productivity. In view of this, a method in which a laser beam is applied inside a wafer to form a peel-off layer and another wafer is peeled off from the wafer with this peel-off layer as a start point has been attempted (Japanese Patent Laid-Open No. 2017-028072).

### SUMMARY OF THE INVENTION

Meanwhile, in order to reduce a thickness of a wafer that is to be peeled off as much as possible, it is required to prevent a crack from being exposed in forming a peel-off layer. Owing to this, a peel-off property is lowered. In order to enhance the peel-off property, a method of applying an ultrasonic wave to a wafer is available. With this method, however, even if an ultrasonic wave is applied to the wafer after a support substrate is bonded to the wafer, the peel-off property is not enhanced sufficiently. Conversely, if the wafer is completely peeled off before the support substrate is bonded to the wafer, handling of the wafer becomes difficult.

Accordingly, it is an object of the present invention to provide a wafer thinning method which is capable of suppressing lowering of the productivity while reducing a wear amount of grindstones.

In accordance with an aspect of the present invention, there is provided a wafer thinning method for a wafer having a first surface and a second surface that is opposite to the first surface, the method including a first support substrate bonding step of bonding a first support substrate to the first surface of the wafer, a separation start point forming step of positioning a focused spot of a laser beam with a wavelength transmittable through the wafer from the second surface side of the wafer inside the wafer, and applying the laser beam while moving the focused spot and the wafer relative to each other in a direction parallel to the second surface, thereby forming separation start points each including a modified layer parallel to the second surface and cracks extending from the modified layer, a first ultrasonic wave applying step of, after the first support substrate bonding step and the separation start point forming step are carried out, applying an ultrasonic wave to the wafer from the second surface side of the wafer, a second support substrate bonding step of, after the first ultrasonic wave applying step is carried out, bonding a second support substrate to the second surface of the wafer, and a thinning step of, after the second support substrate bonding step is carried out, separating the wafer at the separation start points into a first wafer having the first surface and a second wafer having the second surface, thereby thinning the wafer.

Preferably, the wafer thinning method further includes a second ultrasonic wave applying step of, after the second support substrate bonding step is carried out and before the thinning step is carried out, applying the ultrasonic wave to the wafer from the second support substrate side of the wafer.

Preferably, in the first ultrasonic wave applying step, the ultrasonic wave is applied to a first region of the wafer at a first energy density, to thereby form partial peel-off portions which are partially peeled off at the separation start points, and in the second ultrasonic wave applying step, the ultrasonic wave is applied to a second region wider than the first region of the wafer at a second energy density lower than the first energy density, to thereby form a peel-off portion which extends from the partial peel-off portions to the whole region of the wafer.

Preferably, the wafer is a substrate including lithium tantalate. According to the present invention, lowering of the productivity can be suppressed, while a wear amount of grindstones is reduced.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view of a wafer to be processed in a wafer thinning method according to a preferred embodiment of the present invention;

FIG. 2 is a flowchart illustrating a flow of the wafer thinning method according to the embodiment;

FIG. 3 is a perspective view illustrating a first support substrate bonding step depicted in FIG. 2;

FIG. 4 is a side view of the wafer which has undergone the first support substrate bonding step depicted in FIG. 2;

FIG. 5 is a perspective view illustrating a state of a separation start point forming step illustrated in FIG. 2;

FIG. 6 is a partial cross-sectional side view of the state depicted in FIG. 5;

FIG. 7 is a top plan view of the wafer depicted in FIG. 6;

FIG. 8 is a perspective view illustrating a state of a first ultrasonic wave applying step depicted in FIG. 2;

FIG. 9 is a perspective view illustrating a second support substrate bonding step depicted in FIG. 2;

FIG. 10 is a cross-sectional side view of the wafer which has undergone the second support substrate bonding step depicted in FIG. 2;

FIG. 11 is a partial cross-sectional side view illustrating a state of a second ultrasonic wave applying step depicted in FIG. 2;

FIG. 12 is a partial cross-sectional side view illustrating a state of a thinning step depicted in FIG. 2; and

FIG. 13 is a partial cross-sectional side view illustrating a state subsequent to FIG. 12 in the thinning step depicted in FIG. 2.

### DETAILED DESCRIPTION OF THE PREFERRED EMBODIMENT

Hereinafter, a preferred embodiment of the present invention will be described in detail with reference to the drawings. Contents described in the following embodiment do not limit the present invention. Further, components used in the following embodiment may include those that can easily be assumed by persons skilled in the art or substantially the same elements as those known in the art. Moreover, the configurations described below may be suitably used in combination. In addition, the configurations may variously be omitted, replaced, or changed without departing from the scope of the present invention.

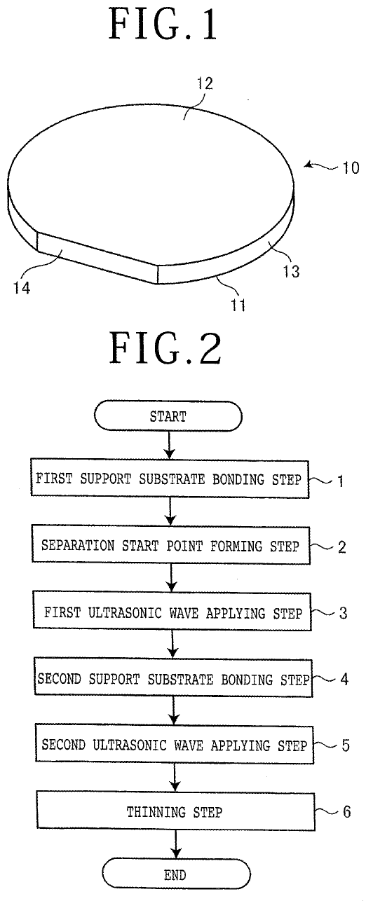

A wafer thinning method for a wafer 10 according to the embodiment of the present invention will be described with reference to the drawings. FIG. 1 is a perspective view of the wafer 10 which is an object to be processed in the wafer thinning method for the wafer 10 according to the embodiment. The wafer 10 in the embodiment is a lithium tantalate substrate made of lithium tantalate, but may be, for example, a lithium niobate substrate. The wafer 10 is formed into a disc-shaped wafer having a thickness of substantially 350 to 500 μm. The wafer 10 has a first surface 11, a second surface 12, a circumferential face 13, and an orientation flat 14.

The first surface 11 is a circular shape and is one end face of the disc-shaped wafer 10. The first surface 11 corresponds to a bonding face which is to be bonded to a first support substrate 20 to be described later. The second surface 12 is a circular shape and is the other end face opposite to the first surface 11 of the disc-shaped wafer 10. The second surface 12 corresponds to another bonding face which is to be bonded to a second support substrate 30 to be described later. The circumferential face 13 is a face continuous to an outer edge of the first surface 11 and an outer edge of the second surface 12. The orientation flat 14 is a plane to be formed at a part of the circumferential face 13 in order to indicate a crystal orientation of the wafer 10.

FIG. 2 is a flowchart illustrating a flow of the wafer thinning method for the wafer 10 according to the embodiment. The wafer thinning method for the wafer 10 includes a first support substrate bonding step 1, a separation start point forming step 2, a first ultrasonic wave applying step 3, a second support substrate bonding step 4, a second ultrasonic wave applying step 5, and a thinning step 6.

### (First Support Substrate Bonding Step 1)

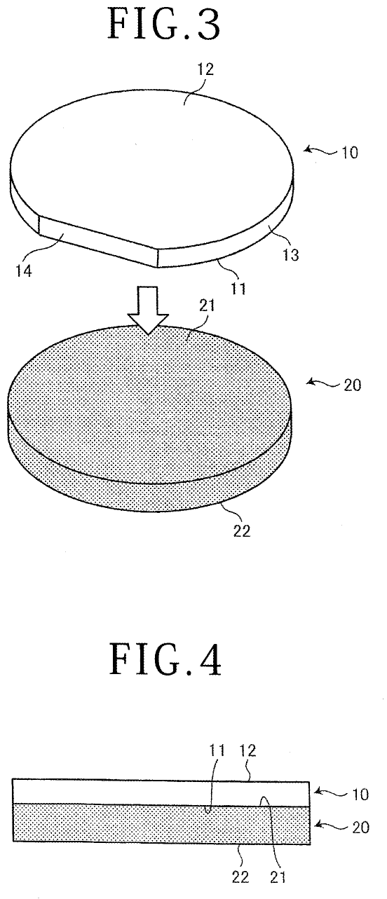

FIG. 3 is a perspective view illustrating the first support substrate bonding step 1 depicted in FIG. 2. FIG. 4 is a side view of the wafer 10 having undergone the first support substrate bonding step 1 depicted in FIG. 2. The first support substrate bonding step 1 is a step of bonding the first support substrate 20 to the first surface 11 of the wafer 10.

The first support substrate 20 is a disc-shaped glass substrate having a diameter same as that of the wafer 10 and a thickness larger than that of the wafer 10 in the embodiment. However, as long as the first support substrate 20 can support the wafer 10 and secure handling capability for the wafer 10, a material (hardness), a size, a thickness, and the like are not limited to particular ones. The first support substrate 20 has a circular-shaped bonding face 21 which is one end face of the first support substrate 20 which is formed into a disc shape, and a circular-shaped face 22 which is the other end face opposite to the bonding face 21.

In the first support substrate bonding step 1, first, as illustrated in FIG. 3, the first surface 11 of the wafer 10 and the bonding face 21 of the first support substrate 20 are opposed to each other at an interval. Then, as illustrated in FIG. 4, the first surface 11 of the wafer 10 and the bonding face 21 of the first support substrate 20 are attached to each other to be bonded.

At this time, in a case in which a bonding layer is provided between the wafer 10 and the first support substrate 20, the bonding layer is stacked on one of the first surface 11 of the wafer 10 and the bonding face 21 of the first support substrate 20, and then, the first surface 11 of the wafer 10 and the bonding face 21 of the first support substrate 20 are attached through the bonding layer to each other. It is to be noted that the bonding layer may be a double-sided adhesive tape in which an adhesive layer is stacked on either side of a base layer, an oxide film, or a layer obtained by applying thereto an adhesive including resin or the like.

### (Separation Start Point Forming Step 2)

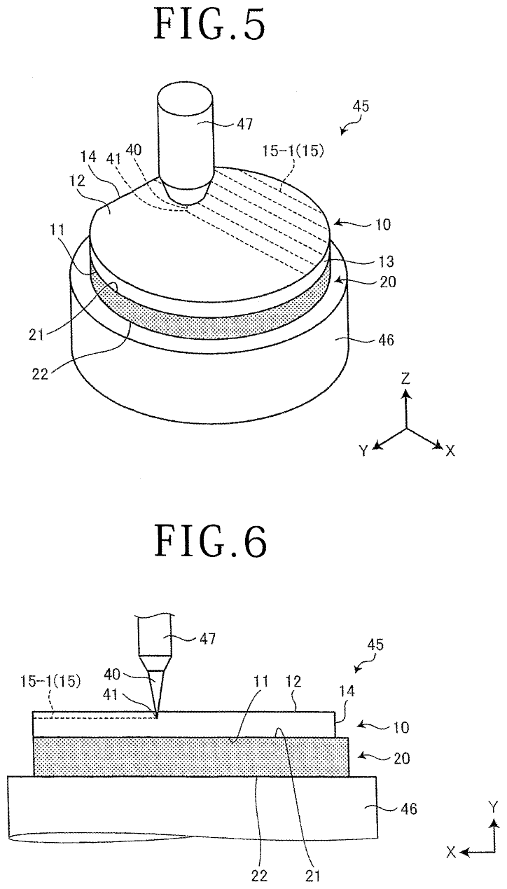

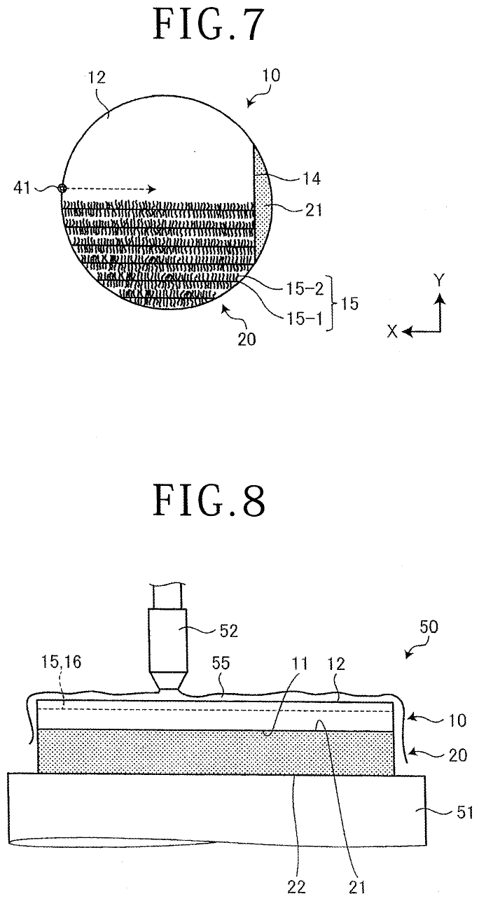

FIG. 5 is a perspective view illustrating a state of the separation start point forming step 2 illustrated in FIG. 2. FIG. 6 is a partial cross-sectional side view of the state depicted in FIG. 5. FIG. 7 is a top plan view of the wafer 10 depicted in FIG. 6. The separation start point forming step 2 may be carried out before the first support substrate bonding step 1 is carried out or after the first support substrate bonding step 1 is carried out. The separation start point forming step 2 is a step of applying a laser beam 40 to the wafer 10 from the second surface 12 side of the wafer 10 to form a separation start point 15 including a modified layer 15-1 parallel to the second surface 12 and a crack 15-2 extending from the modified layer 15-1.

The separation start point forming step 2 is carried out by a laser processing apparatus 45. The laser processing apparatus 45 includes a holding table 46 and a laser beam applying unit 47. The holding table 46 has a holding surface on which the wafer 10 is held, and is rotatable about an axis vertical to the holding surface thereof. The laser beam applying unit 47 applies the laser beam 40 to the wafer 10 held on the holding surface of the holding table 46. The laser processing apparatus 45 further includes an undepicted moving unit which moves the holding table 46 and the laser beam applying unit 47 relative to each other, an undepicted imaging unit which images the wafer 10 held on the holding surface of the holding table 46, and the like. It is to be noted that, in the following description, an X-axis direction is one direction on a horizontal surface. A Y-axis direction is a direction perpendicular to the X-axis direction on the horizontal surface. In addition, in the embodiment, the X-axis direction is a processing feed direction, and the Y-axis direction is an index feed direction.

In the separation start point forming step 2, a focused spot 41 of the laser beam 40 is positioned from the second surface 12 side of the wafer 10 inside the wafer 10, and applies the laser beam 40 to the whole region of the wafer 10, while the focused spot 41 and the wafer 10 are relatively moved in the X-axis and Y-axis directions parallel to the second surface 12. Accordingly, the separation start points 15 each including the modified layer 15-1 parallel to the second surface 12 and the cracks 15-2 extending from the modified layer 15-1 are formed. The laser beam 40 is a laser beam with a wavelength transmittable through the wafer 10, for example, an infrared ray (IR).

The modified layer 15-1 represents a region in a state different from surrounding regions in density, refractive index, mechanical strength, or other physical properties. The modified layer 15-1 is, for example, a melting processing region, a crack region, a dielectric breakdown region, a refractive index change region, and a region in which they are mixed. The modified layer 15-1 is lower in mechanical strength or the like than the other regions of the wafer 10.

In the separation start point forming step 2, first, the face 22 side opposite to the bonding face 21 of the first support substrate 20 is held under suction on the holding surface (upper surface) of the holding table 46. At this time, the orientation flat 14 of the wafer 10 and the index feed direction (Y-axis direction) are aligned in such a manner as to be parallel to each other, i.e., such that a <11-20> direction indicating the crystal orientation of the wafer 10 is parallel to the processing feed direction (X-axis direction). Then, alignment between the wafer 10 and focusing means of a laser beam applying unit 47 is carried out.

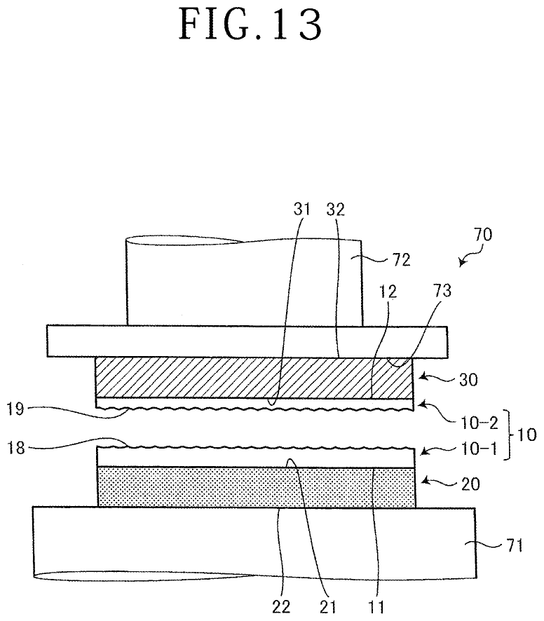

Specifically, the undepicted moving unit moves the holding table 46 to an irradiation region below the laser beam applying unit 47, positioning the focused spot 41 of the laser beam 40 at a predetermined depth inside the wafer 10. The predetermined depth is a depth in a range of 20 to 100 μm from the second surface 12 of the wafer 10 and corresponds to a thickness of a wafer 10-2 having the second surface 12 to be separated from a wafer 10-1 having the first surface 11 in the thinning step 6, which will be described later (see FIG. 13).

In the separation start point forming step 2, next, with the focused spot 41 of the laser beam 40 positioned inside the wafer 10, the laser beam applying unit 47 is moved relative to the holding table 46 in the processing feed direction (X-axis direction). That is, while the focused spot 41 and the wafer 10 are moved relative to each other in one of the directions parallel to the second surface 12 (in the X-axis direction), the laser beam 40 is applied to the wafer 10 from the second surface 12 side.

As a result, the modified layer 15-1 along one of the directions parallel to the second surface 12 (X-axis direction) is formed at the predetermined depth inside the wafer 10. After the laser beam 40 is applied to an outer edge portion of the wafer 10, the focused spot 41 is relatively moved by a predetermined pitch in the index feed direction (Y-axis direction), and another modified layer 15-1 along the processing feed direction (X-axis direction) is similarly formed in the processing feed direction (X-axis direction), so that the modified layers 15-1 are formed in the whole region of the wafer 10.

At this time, the cracks 15-2 extending from the modified layer 15-1 along a direction parallel to the second surface 12 at the predetermined depth inside the wafer 10, and the separation start points 15 each including the modified layer 15-1 and the cracks 15-2 parallel to the second surface 12 are formed. It is to be noted that the direction parallel to the second surface 12 here represents that an inclination relative to a horizontal surface that is an approximate plane obtained by approximating the entire extending cracks 15-2 into a plane is in a range of +5 degrees, preferably +2 degrees. In addition, in the separation start point forming step 2, output of the laser beam 40 is adjusted in such a manner as not to prevent the extending crack 15-2 from being exposed on the second surface 12 side of the wafer 10, to form the modified layer 15-1.

### (First Ultrasonic Wave Applying Step 3)

FIG. 8 is a perspective view illustrating a state of the first ultrasonic wave applying step 3 depicted in FIG. 2. The first ultrasonic wave applying step 3 is carried out after the first support substrate bonding step 1 and the separation start point forming step 2 are carried out. The first ultrasonic wave applying step 3 is a step of applying an ultrasonic wave from the second surface 12 side of the wafer 10 to the wafer 10.

The first ultrasonic wave applying step 3 is carried out by an ultrasonic wave applying apparatus 50. The ultrasonic wave applying apparatus 50 includes a holding table 51, an ultrasonic wave nozzle 52, and an undepicted moving unit which moves the holding table 51 and the ultrasonic wave nozzle 52 relative to each other. As illustrated in FIG. 8, the ultrasonic wave nozzle 52 in the embodiment has a hollow frustoconical section with a width that gets narrower toward its lower end, and a cylindrical section provided extending upward from an upper end of the frustoconical section. A lower end face of the ultrasonic wave nozzle 52 has an opening and is provided so as to face a holding surface of the holding table 51.

The ultrasonic wave nozzle 52 has an ultrasonic transducer and a flow channel through which liquid 55 supplied from an undepicted liquid supply source passes incorporated therein. The ultrasonic transducer is expanded and contracted by application of alternating-current (AC) power to produce ultrasonic wave vibration. The liquid 55 is, for example, pure water. The liquid 55 is supplied at a position at which vibration produced by the ultrasonic transducer is to be transmitted, inside the ultrasonic wave nozzle 52. The liquid 55 to which the vibration produced by the ultrasonic transducer has been transmitted passes through the flow channel of the ultrasonic wave nozzle 52 and is then supplied to the second surface 12 of the wafer 10 held on a holding surface of the holding table 51 through the first support substrate 20, from the opening formed in the lower end face of the ultrasonic wave nozzle 52.

In the first ultrasonic wave applying step 3, first, the face 22 opposite to the bonding face 21 of the first support substrate 20 which is bonded to the wafer 10 having the separation start points 15 formed therein is held under suction on the holding surface (upper surface) of the holding table 51. Then, the lower end face of the ultrasonic wave nozzle 52 is made to face, at a predetermined interval, the second surface 12 of the wafer 10 held on the holding surface of the holding table 51 through the first support substrate 20 and is brought close thereto.

Next, in the first ultrasonic wave applying step 3, AC power is applied to the ultrasonic transducer incorporated in the ultrasonic wave nozzle 52, and in a state in which the ultrasonic transducer is vibrated, the liquid 55 is supplied to the ultrasonic wave nozzle 52 from the undepicted liquid supply source. At this time, the liquid 55 is supplied from the opening formed in the lower end face of the ultrasonic wave nozzle 52 to the second surface 12 of the wafer 10. The ultrasonic transducer is vibrated in a state in which a portion between the ultrasonic wave nozzle 52 and the second surface 12 of the wafer 10 is immersed in the liquid 55, so that ultrasonic wave vibration produced in the ultrasonic wave nozzle 52 is applied to the second surface 12 of the wafer 10 through the liquid 55.

Next, in the first ultrasonic wave applying step 3, while the liquid 55 is being supplied to the second surface 12 of the wafer 10 and the ultrasonic transducer is being vibrated, the undepicted moving unit moves the holding table 51 and the ultrasonic wave nozzle 52 relative to each other. As a result, with the liquid 55 serving as a medium, the ultrasonic wave vibration is applied to a predetermined region (first region) in the second surface 12 of the wafer 10.

Owing to the ultrasonic wave vibration, a new crack 15-2 (see FIG. 7) extends at the separation start point 15 in the wafer 10, and a partial peel-off portion 16 which is partially peeled off is formed in the wafer 10. In the partial peel-off portion 16, with the separation start points 15 as an interface, a portion on the first surface 11 side and a portion on the second surface 12 side are separated from each other in the wafer 10. After ultrasonic waves are applied to the first region of the wafer 10, supply of the liquid 55 is stopped, and the ultrasonic wave nozzle 52 is spaced from the second surface 12 of the wafer 10.

### (Second Support Substrate Bonding Step 4)

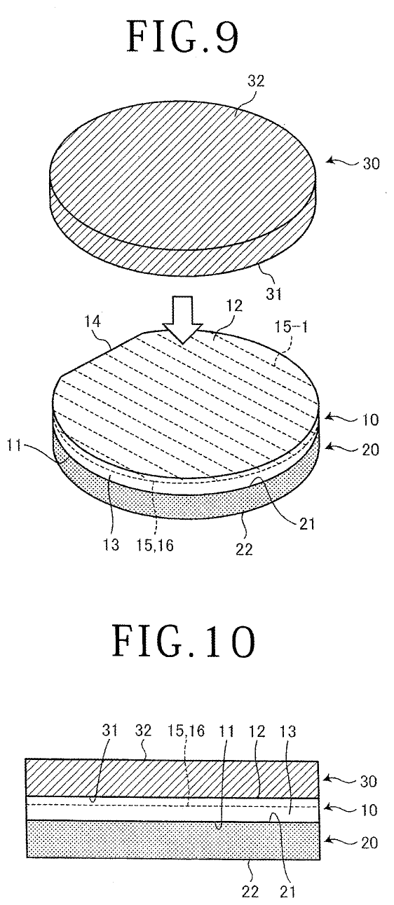

FIG. 9 is a perspective view illustrating the second support substrate bonding step 4 depicted in FIG. 2. FIG. 10 is a cross-sectional side view of the wafer 10 which has undergone the second support substrate bonding step 4 depicted in FIG. 2. The second support substrate bonding step 4 is carried out after the first ultrasonic wave applying step 3 is carried out. The second support substrate bonding step 4 is a step of bonding the second support substrate 30 to the second surface 12 of the wafer 10.

The second support substrate 30 is made of a material having a low thermal expansion coefficient. The second support substrate 30 in the embodiment is a silicon substrate including silicon (Si) but may be a substrate including sapphire (Al₂O₃) or the like. The second support substrate 30 is formed into a circular plate shape having the same diameter as that of the wafer 10 and a thickness larger than that of the wafer 10. The second support substrate 30 has a circular-shaped bonding face 31 that is one end face of the second support substrate 30 which is formed into a disc shape, and a circular-shaped face 32 that is the other end face opposite to the bonding face 31.

In the second support substrate bonding step 4, first, as illustrated in FIG. 9, the first support substrate 20 is bonded to the first surface 11 side, and the second surface 12 of the wafer 10 having the partial peel-off portions 16 formed at the separation start points 15 and the bonding face 31 of the second support substrate 30 are opposed to each other at an interval. Then, as illustrated in FIG. 10, the second surface 12 of the wafer 10 is attached and bonded to the bonding face 31 of the second support substrate 30.

At this time, in a case in which a bonding layer is provided between the wafer 10 and the second support substrate 30, the bonding layer is stacked on one of the second surface 12 of the wafer 10 and the bonding face 31 of the second support substrate 30, and then, the second surface 12 of the wafer 10 and the bonding face 31 of the second support substrate 30 are attached through the bonding layer to each other. It is to be noted that the bonding layer may be a double-sided adhesive tape in which an adhesive layer is stacked on either side of a base layer, an oxide film, or a layer obtained by applying thereto an adhesive including resin or the like.

### (Second Ultrasonic Wave Applying Step 5)

FIG. 11 is a partial cross-sectional side view illustrating a state of the second ultrasonic wave applying step 5 depicted in FIG. 2. The second ultrasonic wave applying step 5 is carried out after the second support substrate bonding step 4 is carried out and before the thinning step 6 is carried out. The second ultrasonic wave applying step 5 is a step of applying an ultrasonic wave to the wafer 10 from the second support substrate 30 side.

The second ultrasonic wave applying step 5 is carried out by an ultrasonic wave applying apparatus 60. The ultrasonic wave applying apparatus 60 includes a holding table 61, an ultrasonic horn 62, a liquid supply nozzle 63, and an undepicted moving unit which moves the holding table 61 relative to the ultrasonic horn 62 and the liquid supply nozzle 63. It is to be noted that the ultrasonic horn 62 and the liquid supply nozzle 63 may be included in a second ultrasonic wave applying unit mounted in part of the ultrasonic wave applying apparatus 50 illustrated in FIG. 8. In this case, the holding table 51 illustrated in FIG. 8 may be used also as the holding table 61.

As illustrated in FIG. 11, the ultrasonic horn 62 in the embodiment is a cylindrical vibration member larger in width than a cylindrical section of the ultrasonic wave nozzle 52 illustrated in FIG. 8. A lower end face of the ultrasonic horn 62 is provided in such a manner as to face a holding surface of the holding table 61. The ultrasonic horn 62 has an ultrasonic transducer incorporated therein, and the ultrasonic transducer is similar to the ultrasonic transducer incorporated in the ultrasonic wave nozzle 52 illustrated in FIG. 8. The ultrasonic horn 62 is vibrated in whole according to vibration of the ultrasonic transducer incorporated therein.

The liquid supply nozzle 63 is provided at a position adjacent to the ultrasonic horn 62, to supply liquid 65 from an undepicted liquid supply source. The liquid 65 is, for example, pure water. The liquid 65 supplied from the undepicted liquid supply source passes through a flow channel in the liquid supply nozzle 63 and is then supplied to the face 32 opposite to the bonding face 31 of the second support substrate 30 held on the holding surface of the holding table 61 through the first support substrate 20 and the wafer 10, from an opening formed in a lower end face of the liquid supply nozzle 63.

In the second ultrasonic wave applying step 5, first, the face 22 opposite to the bonding face 21 of the first support substrate 20 bonded to the wafer 10 to which the second support substrate 30 is bonded is held under suction on the holding surface (upper surface) of the holding table 61. It is to be noted that, in a case in which the holding table 61 serves as the holding table 51 illustrated in FIG. 8 and the second support substrate bonding step 4 is carried out on the holding table 51, this step may be omitted. Subsequently, the lower end face of the ultrasonic horn 62 is made to face, at a predetermined interval, the face 32 opposite to the bonding face 31 of the second support substrate 30 held on the holding surface of the holding table 61 through the first support substrate 20 and the wafer 10 and is brought close thereto.

Next, in the second ultrasonic wave applying step 5, AC power is applied to the ultrasonic transducer incorporated in the ultrasonic horn 62, and in a state in which the ultrasonic horn 62 is vibrated in whole, the liquid 65 is supplied to the lower end face of the ultrasonic horn 62 from the undepicted liquid supply source through the liquid supply nozzle 63. At this time, the liquid 65 is supplied to the face 32 opposite to the bonding face 31 of the second support substrate 30. The ultrasonic horn 62 is vibrated in a state in which a portion between the ultrasonic horn 62 and the face 32 of the second support substrate 30 is immersed in the liquid 65, so that ultrasonic wave vibration thus produced is applied to the face 32 of the second support substrate 30 through the liquid 65.

Subsequently, in the second ultrasonic wave applying step 5, while the liquid 65 is being supplied to the face 32 of the second support substrate 30 and the ultrasonic horn 62 is being vibrated, the undepicted moving unit moves the holding table 61 and the ultrasonic horn 62 relative to each other. As a result, with the liquid 65 serving as a medium, the ultrasonic wave vibration is applied to a predetermined region (second region) in the face 32 of the second support substrate 30.

An area of the lower end face of the ultrasonic horn 6 is larger than an area of the opening provided in the lower end face of the ultrasonic wave nozzle 52 illustrated in FIG. 8. Accordingly, the second region is larger than the first region to which the ultrasonic waves are applied in the first ultrasonic wave applying step 3. In addition, an energy density (first energy density) of the ultrasonic wave applied with use of the ultrasonic wave nozzle 52 in the first ultrasonic wave applying step 3 illustrated in FIG. 8 is greater than an energy density (second energy density) of the ultrasonic wave applied with use of the ultrasonic horn 62 in the second ultrasonic wave applying step 5 illustrated in FIG. 11.

It is to be noted that, as an ultrasonic wave application condition in the first ultrasonic wave applying step 3 illustrated in FIG. 8, it is preferable that an opening diameter of the ultrasonic wave nozzle 52 be substantially 5 to 30 mm and that the output of the AC power to be applied to the ultrasonic transducer be substantially 10 to 100 W. In addition, as an ultrasonic wave application condition in the second ultrasonic wave applying step 5 illustrated in FIG. 11, it is preferable that the lower end face of the ultrasonic horn 62 be a square or rectangular shape with a size of substantially 50 mm×50 mm to 200 mm×200 mm and that the output of the AC power to be applied to the ultrasonic transducer be substantially 50 to 150 W.

In the second ultrasonic wave applying step 5, in the wafer 10, the ultrasonic wave vibration leads to extension of a new crack 15-2 (see FIG. 7) at the separation start point 15, and a peel-off portion 17 is formed in the whole region of the wafer 10 from the partial peel-off portions 16 formed at the separation start points 15. At the peel-off portion 17, with the separation start points 15 as an interface, the wafer 10 is separated into two wafers, i.e., a wafer on the first surface 11 side and a wafer on the second surface 12 side.

That is, in the first ultrasonic wave applying step 3 illustrated in FIG. 8, application of the ultrasonic wave having the first energy density to the first region of the wafer 10 leads to formation of the partial peel-off portions 16 in which peeling-off is partially generated at the separation start points 15, while, in the second ultrasonic wave applying step 5 illustrated in FIG. 11, application of the ultrasonic wave having the second energy density lower than the first energy density to the second region larger than the first region leads to formation of the peel-off portion 17 which extends from the partial peel-off portions 16 to the whole region of the wafer 10. After the ultrasonic waves are applied to the second region of the wafer 10, supply of the liquid 65 is stopped, and the ultrasonic horn 62 is spaced from the face 32 of the second support substrate 30. It is to be noted that, in the present invention, the second ultrasonic wave applying step 5 may be omitted.

### (Thinning Step 6)

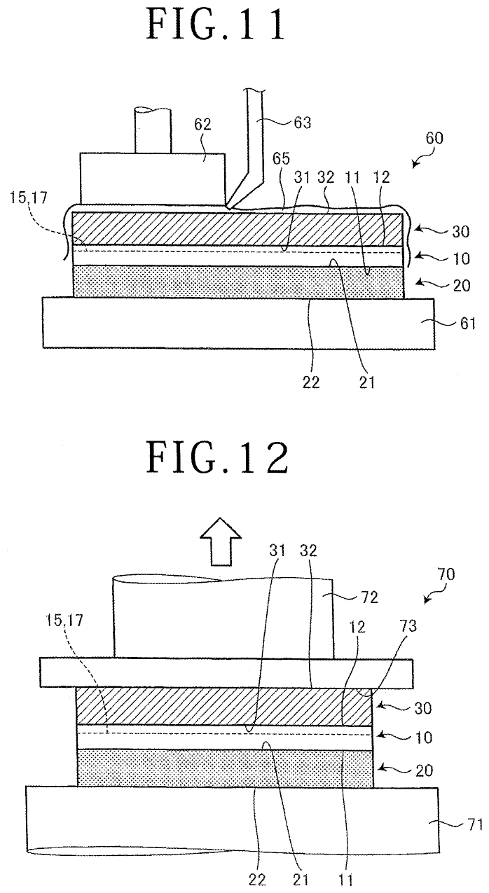

FIG. 12 is a partial cross-sectional side view illustrating a state of the thinning step 6 depicted in FIG. 2. FIG. 13 is a partial cross-sectional side view illustrating a state subsequent to FIG. 12 in the thinning step 6 depicted in FIG. 2. The thinning step 6 is carried out after the second ultrasonic wave applying step 5 is carried out. It is to be noted that, in a case in which the second ultrasonic wave applying step 5 is omitted, the thinning step 6 is carried out after the second support substrate bonding step 4 is carried out. The thinning step 6 is a step of thinning the wafer 10.

The thinning step 6 is carried out by a peel-off apparatus 70. The peel-off apparatus 70 includes a holding table 71, a peel-off unit 72, and an undepicted moving unit which brings the holding table 71 and the peel-off unit 72 close to each other and apart from each other. Note that the peel-off unit 72 may be mounted in part of the ultrasonic wave applying apparatus 50 illustrated in FIG. 8 and the ultrasonic wave applying apparatus 60 illustrated in FIG. 11, and in this case, the holding table 71 may serve as the holding table 51 illustrated in FIG. 8 and the holding table 61 illustrated in FIG. 11.

The peel-off unit 72 has a suction plate 73 having a plurality of suction ports provided in its lower surface. The plurality of suction ports are in communication with an undepicted suction source through a flow channel provided in the suction plate 73. The peel-off apparatus 70 causes the holding table 71 to hold under suction one face of an object and causes the suction plate 73 to hold under suction the other face of the object, casing the holding table 71 and the peel-off unit 72 to be separated from each other. As a result, the object is peeled off and separated into the object on the one face side and the object on the other face side.

In the thinning step 6, first, the face 22 opposite to the bonding face 21 of the first support substrate 20 bonded to the wafer 10 is held under suction on a holding surface (upper surface) of the holding table 71. It is to be noted that, in a case in which the holding table 71 serves as the holding table 61 illustrated in FIG. 11, this step may be omitted. Then, a lower end face of the suction plate 73 of the peel-off unit 72 is brought close to the face 32 opposite to the bonding face 31 of the second support substrate 30 held on the holding surface of the holding table 71 through the first support substrate 20 and the wafer 10, and the face 32 of the second support substrate 30 is held under suction by the suction plate 73.

As illustrated in FIG. 13, then, the peel-off unit 72 is spaced from the holding table 71 with the face 32 of the second support substrate 30 held under suction by the suction plate 73. As a result, the wafer 10 is pulled in up and down directions and separated, with the separation start points 15 as an interface, into the wafer 10-1 having the first surface 11 of the wafer 10 and the wafer 10-2 having the second surface 12 of the wafer 10. That is, the wafer 10 is separated at the separation start points 15 into the wafer 10-1 having the first surface 11 and the wafer 10-2 having the second surface 12, and as a result, a thickness of the wafer 10 is reduced to a thickness of the wafer 10-2.

The wafer 10-2 thus thinned becomes a bonded wafer including the second support substrate 30, for example, and a peel-off surface 19 of the wafer 10-2 is ground to be flat, thereby being processed to be a device wafer. The wafer 10-1 having the first surface 11 from which the wafer 10-2 has been peeled off has a peel-off surface 18 ground to be flat, and, for example, the resultant flat ground surface becomes a new second surface 12. As a result, the new second surface 12 is used as a recycle wafer, which is reused as a wafer 10. In this case, the first support substrate bonding step 1 of the wafer thinning method for the wafer 10, illustrated in the flowchart of FIG. 2, is omitted, and the steps from the separation start point forming step 2 to the thinning step 6 are repeatedly carried out, thereby producing a plurality of thinned wafers 10-2. It is to be noted that the peel-off surface 18 of the wafer 10-1 having the first surface 11 and the peel-off surface 19 of the wafer 10-2 having the second surface 12 may be subjected to application of an ultrasonic wave before being ground, resulting in removal of peeling swarf therefrom.

As has been described above, in the wafer thinning method for the wafer 10 according to the embodiment, further application of an ultrasonic wave to the wafer 10 having the separation start points 15 formed therein leads to formation of the partial peel-off portions 16 serving as the start points for peeling off, thereby enhancing the peel-off property. That is, in such a manner as to prevent the crack 15-2 from extending excessively in the separation start point forming step 2, the output of the laser beam 40 to be applied is suppressed, for example, so that the wafer 10-2 to be peeled off can be reduced in thickness as much as possible, even in a case in which the peel-off property at a point at which the separation start points 15 are formed becomes low. Accordingly, an amount of grinding the wafer 10-2 which has been peeled off can be reduced, thereby providing such advantages that lowering of the productivity can be suppressed while a wear amount of the grindstones can be reduced.

Moreover, after the ultrasonic waves are applied to the wafer 10 to form the partial peel-off portions 16, the second support substrate 30 is bonded to the second surface 12 side of the wafer 10, and the ultrasonic waves are applied through the second support substrate 30 to the wafer 10 again, thereby forming the peel-off portion 17 extending from the partial peel-off portions 16 to the whole region of the wafer 10. As a result, the peel-off property can further be enhanced. In this manner, the ultrasonic waves are applied in two steps, so that it is possible to prevent the wafer 10 from breaking in peeling, while the peel-off property is significantly enhanced.

The present invention is not limited to the details of the above described preferred embodiment. The scope of the invention is defined by the appended claims and all changes and modifications as fall within the equivalence of the scope of the claims are therefore to be embraced by the invention. cm What is claimed is:

1. A wafer thinning method for a wafer having a first surface and a second surface that is opposite to the first surface, the method comprising:
a first support substrate bonding step of bonding a first support substrate to the first surface of the wafer;
a separation start point forming step of positioning a focused spot of a laser beam with a wavelength transmittable through the wafer from the second surface side of the wafer inside the wafer, and applying the laser beam while moving the focused spot and the wafer relative to each other in a direction parallel to the second surface, thereby forming separation start points each including a modified layer parallel to the second surface and cracks extending from the modified layer;
a first ultrasonic wave applying step of, after the first support substrate bonding step and the separation start point forming step are carried out, applying an ultrasonic wave to the wafer from the second surface side of the wafer;
a second support substrate bonding step of, after the first ultrasonic wave applying step is carried out, bonding a second support substrate to the second surface of the wafer; and
a thinning step of, after the second support substrate bonding step is carried out, separating the wafer at the separation start points into a first wafer having the first surface and a second wafer having the second surface, thereby thinning the wafer.

2. The wafer thinning method according to claim 1, further comprising:
a second ultrasonic wave applying step of, after the second support substrate bonding step is carried out and before the thinning step is carried out, applying the ultrasonic wave to the wafer from the second support substrate side of the wafer.

3. The wafer thinning method according to claim 2,
wherein, in the first ultrasonic wave applying step, the ultrasonic wave is applied to a first region of the wafer at a first energy density, to thereby form partial peel-off portions which are partially peeled off at the separation start points, and,
in the second ultrasonic wave applying step, the ultrasonic wave is applied to a second region wider than the first region of the wafer at a second energy density lower than the first energy density, to thereby form a peel-off portion which extends from the partial peel-off portions to the whole region of the wafer.

4. The wafer thinning method according to claim 1,
wherein the wafer is a substrate including lithium tantalate.
